(19) United States
(12) Patent Application Publication
(10) Pub. No.: US 2016/0293670 A1
(43) Pub. Date: Oct. 6, 2016

(54) AMOLED DISPLAY PANEL AND MANUFACTURING METHOD THEREOF, AND DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Hefei, Anhui (CN)

(72) Inventor: Peng Chen, Beijing (CN)

(21) Appl. No.: 14/891,965

(22) PCT Filed: Feb. 27, 2015
(86) PCT No.: PCT/CN2015/073339

§ 371 Date: Nov. 17, 2015

(30) Foreign Application Priority Data
Nov. 10, 2014 (CN) 201410628591.7

(51) Int. Cl. H01L 27/32; H01L 51/52; H01L 51/56; H01L 51/50

(52) U.S. Cl. CPC H01L 27/322; H01L 27/3246; H01L 27/3248; H01L 51/5088; H01L 51/5092; H01L 51/5056; H01L 51/5072; H01L 51/5271; H01L 51/5284; H01L 51/56; H01L 2227/323

(57) ABSTRACT

Embodiments of the invention disclose an AMOLED display panel and a manufacturing method thereof, which pertain to the field of display technology, and can solve a technical problem of a thickness of a full color display bottom-emitting type AMOLED display panel being large. The AMOLED display panel comprises an array substrate having a plurality of subpixels, a pixel defining layer located on a surface of the array substrate, and OLED display structures located on a surface of the pixel defining layer, white light emitted from the OLED display structures is incident onto the array substrate, the pixel defining layer is formed by a color filter layer; wherein the color filter layer comprises a plurality of color units having different colors, and the color units correspond to the subpixels respectively.

### CROSS-REFERENCE TO RELATED APPLICATION

This application is a Section 371 National Stage Application of International Application No. PCT/CN2015/073339, filed on 27 Feb. 2015, entitled “AMOLED DISPLAY PANEL AND MANUFACTURING METHOD THEREOF, AND DISPLAY DEVICE”, which has not yet published, and which claims priority to Chinese Application No. 201410628591.7, filed on 10 Nov. 2014, incorporated herein by reference in their entirety.

### FIELD OF THE INVENTION

Embodiments of the invention relate to the field of display technology, and specifically to an AMOLED display panel and a manufacturing method thereof, and a display device.

### BACKGROUND OF THE INVENTION

OLED (Organic Light Emitting Diode) display is a self-luminous display. It can be divided into PMOLED (Passive Matrix Driving OLED) display and AMOLED (Active Matrix Driving OLED) display based on its drive mode. AMOLED display device is becoming more and more popular in various display fields that require a high performance for its advantages of low manufacturing cost, high response speed, power saving, DC drive mode which can used in portable devices, wide working temperature range and so on.

In prior arts, in order to realize a full colorization of an AMOLED display, a WOLED+CF method (i.e., a “white light OLED+color filter” method) may be used, in which a color filter is usually disposed on a color filter substrate, and then the color filter substrate is assembled with an array substrate.

Specifically, a bottom-emitting type AMOLED display may comprise an array substrate, and a color file substrate and an OLED display structure disposed respectively on either side of the array substrate. Wherein, in the bottom-emitting type AMOLED display, the color filter substrate is disposed on a surface of the array substrate that is adjacent to a light-emitting side of the AMOLED display, such that light is emitted from the array substrate through the color filter substrate.

During the process of using the WOLED+CF method, however, in addition to adding the color filter substrate, an underlying substrate made of glass also needs to be provided in order to improve reliability of an AMOLED display. Typically, a thickness of an underlying substrate is approximately 500 μm, which significantly increases the thickness of the AMOLED display panel, and is disadvantageous in achieving a light and thin AMOLED display panel.

### SUMMARY OF THE INVENTION

Embodiments of the invention provide an AMOLED display panel and a manufacturing method thereof, which pertain to the field of display technology, and can solve a technical problem of a thickness of a full color display bottom-emitting type AMOLED display panel being large. In order to achieve the above object, according to one aspect of embodiments of the invention, there is provided an AMOLED display panel. The AMOLED display panel comprises an array substrate having a plurality of subpixels; a pixel defining layer located on a surface of the array substrate; and a plurality of OLED display structures corresponding to the subpixels respectively. The pixel defining layer comprises a color filter layer; and the color filter layer comprises a plurality of color units having different colors, and the color units correspond to the subpixels respectively.

According to an exemplary embodiment, the pixel defining layer is only consisted of the color filter layer.

According to an exemplary embodiment, each OLED display structure comprises a first electrode, a second electrode opposite to the first electrode, and an organic material functional layer disposed between the first electrode and the second electrode; and the organic material functional layer comprises a hole injection layer, a hole transportation layer, an organic light emitting layer, an electron transportation layer, and an electron injection layer disposed successively from the first electrode to the second electrode.

According to an exemplary embodiment, the second electrode is formed of a material having a high reflectivity.

According to an exemplary embodiment, the material comprises at least one of aluminum and silver.

According to an exemplary embodiment, the first electrode is connected to a drain electrode of a thin film transistor in the subpixels through a via-hole formed in the pixel defining layer.

According to an exemplary embodiment, the organic light emitting layer comprises a red organic light emitting layer, a green organic light emitting layer, and a blue organic light emitting layer arranged in stack in an arbitrary order.

According to an exemplary embodiment, the organic light emitting layer comprises a red organic light emitting layer, a green organic light emitting layer, and a blue organic light emitting layer disposed side by side in the same layer in an arbitrary order.

According to an exemplary embodiment, the organic light emitting layer has a thickness which is the same as that of the pixel defining layer.

According to an exemplary embodiment, a thickness of the color filter layer is in range of 1 μm to 4 μm.

According to an exemplary embodiment, the thickness of the color filter layer is in a range of 3 μm to 4 μm.

According to another aspect of the invention, there is provided a display device comprising the AMOLED display panel as stated above.

According to further aspect of the invention, there is provided a method for manufacturing an AMOLED display panel. The method comprises steps of: forming an array substrate having a plurality of subpixels; forming a pixel defining layer on a surface of the array substrate, the pixel defining layer comprising a color filter layer, the color filter layer comprising a plurality of color units having different colors, each of the color units corresponds to one of the subpixels; and forming a plurality of OLED display structures that corresponds to the subpixels respectively.

According to an exemplary embodiment, when the subpixel comprises a pixel electrode, the step of forming the pixel defining layer comprises: forming, on the surface of the array substrate, a pixel defining layer only consisted of the color filter layer.

According to an exemplary embodiment, the step of forming the OLED display structure comprises: forming a via-hole in the pixel defining layer; and forming the OLED display structure in the via-hole.

According to an exemplary embodiment, the step of forming the OLED display structure comprises: forming a first electrode; forming an organic material functional layer on the first electrode; and forming a second electrode on the organic material functional layer.

According to an exemplary embodiment, the step of forming organic material functional layer comprises: forming a hole injection layer, a hole transportation layer, an organic light emitting layer, an electron transportation layer, and an electron injection layer successively through evaporation coating processes.

According to an exemplary embodiment, the step of forming the organic light emitting layer comprises: forming, through evaporation coating processes, a red organic light emitting layer, a green organic light emitting layer and a blue organic light emitting layer stacked up in an arbitrary order.

According to an exemplary embodiment, the step of forming the organic light emitting layer comprises: forming, through mask exposure processes, a red organic light emitting layer, a green organic light emitting layer, and a blue organic light emitting layer arranged side by side in an arbitrary order in the same layer.

According to an exemplary embodiment, the step of forming the second electrode comprises: forming the second electrode from a material having a high reflectivity.

Embodiments of the invention provide an AMOLED display panel and a manufacturing method thereof. The AMOLED display panel comprises an array substrate having a plurality of subpixels, a pixel defining layer disposed on a surface of the array substrate, and OLED displaying structures located on a surface of the pixel defining layer, wherein the OLED displaying structures correspond to the subpixels respectively, white light emitted by the OLED displaying structures irradiates to the array substrate, such that a bottom-emitting type AMOLED display panel is formed. Additionally, the pixel defining layer comprises a color filter layer, wherein the color filter layer comprises a plurality of color units having different colors such as red, green, and blue, and the color units correspond to the subpixels respectively. With such a configuration, a pixel unit may be formed by three subpixels respectively corresponding to a red, a green, and a blue color unit, so that a full color display of the AMOLED display panel can be realized. Since the pixel defining layer is constituted by a color filter layer, there is no need to add a color filter substrate onto a surface of the array substrate adjacent to a light emitting side of the AMOLED display panel. A thickness of the AMOLED display panel may thereby be reduced.

### BRIEF DESCRIPTION OF THE DRAWINGS

In order to clearly explicate technical solutions according to embodiments of the invention and technical solutions in prior arts, an introduction to the attached drawings which will be used hereafter to describe the embodiments and prior arts is provided as follows. Apparently, the following attached drawings only show some embodiments of the invention, and other drawings will be apparently obtained by those skilled in the art based on the following attached drawings without paying a creative labor.

FIG. 1a is an illustrative view showing a structure of an AMOLED display panel provided by an embodiment of the invention;

FIG. 1b is illustrative top view showing a structure of an array substrate in prior art;

FIG. 1c is an illustrative view showing a structure of a pixel defining layer provided by an embodiment of the invention;

FIG. 2a is an illustrative view showing a structure of another AMOLED display panel provided by an embodiment of the invention;

FIG. 2b is an illustrative view showing a structure of another AMOLED display panel provided by an embodiment of the invention;

FIG. 3a is an illustrative view showing a structure of an organic light emitting layer in an OLED displaying structure provided by an embodiment of the invention;

FIG. 3b is an illustrative view showing a structure of an organic light emitting layer in another OLED displaying structure provided by an embodiment of the invention;

FIG. 4a is an illustrative view showing a structure of another pixel defining layer provided by an embodiment of the invention;

FIG. 4b is an illustrative view showing a structure of another AMOLED display panel provided by an embodiment of the invention; and

FIG. 5 is a flowchart of a manufacturing method for an AMOLED display panel provided by an embodiment of the invention.

A list of reference numbers:
10—array substrate;
100—subpixel;
101—pixel electrode;
110—underlying substrate;
111—gate insulation layer;
112—insulation layer;
20—pixel defining layer;
201—color unit;
202—black matrix;
30—OLED displaying structure;
301—first electrode;
302—second electrode;
303—hole injection layer;
304—hole transportation layer;
305—organic light emitting layer;
306—electron transportation layer;
307—electron injection layer;
310—organic material functional layer;
40—TFT;
401—gate electrode;
402—drain electrode;
403—source electrode.

### DETAILED DESCRIPTION OF PREFERRED EMBODIMENTS OF THE INVENTION

A detailed description of technical solutions according to embodiments of the present disclosure will be provided hereinafter with reference to the attached drawings. Apparently, the following described embodiments are just some exemplary ways, not all possible ways, of implementing the invention. All other embodiments obtained by those skilled in the art based on the described embodiments of the invention without a creative work shall fall within the scope of the invention.

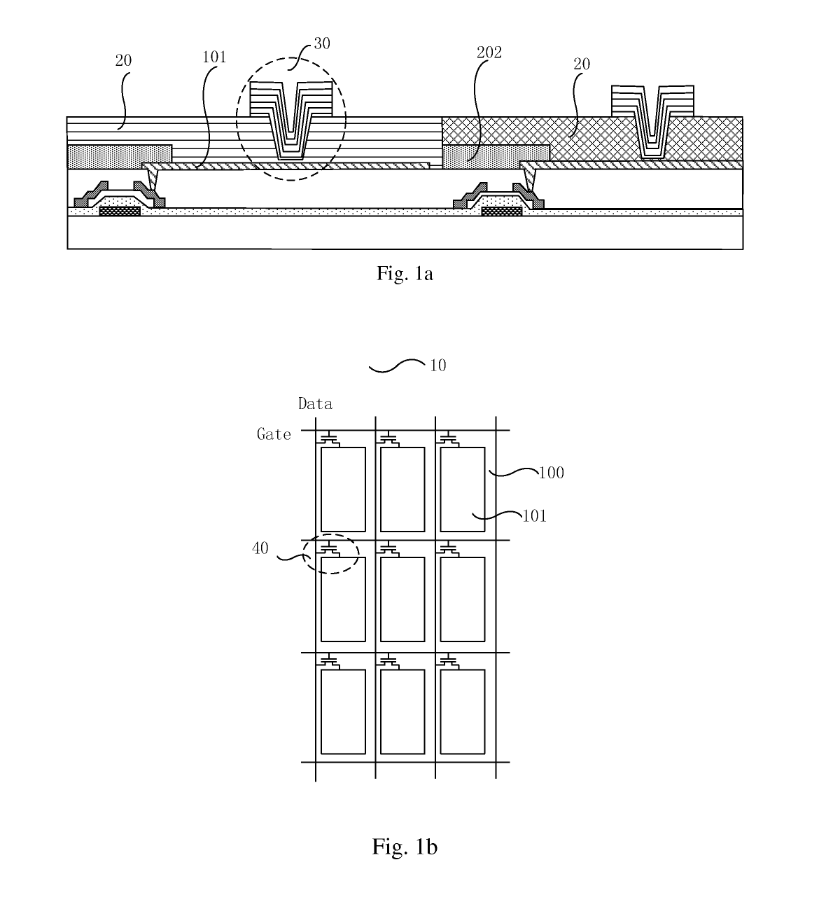

As shown in FIG. 1a, an AMOLED display panel according to an embodiment of the invention may comprise an array substrate 10 having a plurality of subpixels 100, a pixel defining layer 20 disposed on a surface of the array substrate 10, and OLED displaying structures 30 located on a surface of the pixel defining layer 20, and the OLED displaying structures 30 correspond to the subpixels 100 respectively, as shown in FIG. 1b. White light emitted from the OLED displaying structures 30 is incident onto the array substrate 10.

Additionally, the pixel defining layer 20 may comprise a color filter layer, wherein the color filter layer may comprise a plurality of color units 201 having different colors, and each color unit 201 corresponds to one of the subpixels 100.

Specifically, the pixel defining layer 20, for example, may consist of the spaced-apart color filter units and a black matrix 202 as shown in FIG. 1c. The color units 201 correspond to pixel electrodes 101 of the subpixels 100 respectively, and the black matrix 202 corresponds to regions of subpixels 100 except the pixel electrodes 101. With such a configuration, the black matrix 202 can shield a control circuit (e.g., a region where a TFT 40 is located) disposed on the array substrate 10, so as to prevent light from being irradiated to the above control circuit and causing a damage to the circuit.

The AMOLED display panel according to an embodiment of the invention may comprise an array substrate having a plurality of subpixels, a pixel defining layer disposed on a surface of the array substrate, and OLED displaying structures located on a surface of the pixel defining layer and corresponding to the subpixels respectively, white light emitted by the OLED displaying structures is incident onto the array substrate, such that a bottom-emitting type AMOLED display panel is formed. Additionally, the pixel defining layer comprises a color filter layer, wherein the color filter layer comprises a plurality of color units having different colors (such as red, green, and blue), and the color units correspond to the subpixels respectively. With such a configuration, a pixel unit may be formed by three subpixels respectively corresponding to red, green, and blue color units respectively, so that a full color display of the AMOLED display panel can be realized. Since the pixel defining layer is consisted of a color filter layer, there is no need to add a color filter substrate onto a surface of the array substrate adjacent to a light emitting side of the AMOLED display panel. A thickness of the AMOLED display panel may thereby be reduced.

To be noted, firstly, in the array substrate 10 (as shown in the top view of FIG. 1b), the plurality of subpixels 100 are formed by several gate lines Gate and data lines Data crisscrossed with each other. Each subpixel 100 is provided with a thin film transistor 40 (TFT). The TFT 40 is a semiconductor unit having a switch function, and it may be a top-gate type TFT or a bottom-gate type TFT, which is not limited herein.

Wherein terms “top-gate” and “bottom-gate” are defined based on positions of a gate electrode 401, a drain electrode 402 and a source electrode 403 relative to the underlying substrate. For example, as compared with the drain electrode 402 and the source electrode 403, if the gate electrode 401 is closer to the underlying substrate 110 of the array substrate, then the TFT 40 is a bottom-gate type TFT. As compared with the gate electrode 401, if the drain electrode 402 and the source electrode 403 are closer to the underlying substrate 110 of the array substrate, then the TFT 40 is a top-gate type TFT. In the embodiments of the invention, a bottom-gate type TFT 40 is taken as an example.

Secondly, the pixel defining layer 20 formed by the color filter layer may comprise a plurality of color units 201 having different colors. Take a RGB display device as an example, colors of the color units 201 may comprise red (R), green (G), and blue (B). In such a manner, three subpixels on the array substrate 10, which correspond to a red color unit 210, a green color unit 210 and a blue color unit 210 respectively, may form a pixel unit.

Take a RGBW display device as another example, the color units 201 may be a red (R) color unit, a green (G) color unit, a blue (B) color unit, or a transparent color unit 201 which does not have any color, such that white light emitted by an OLED can penetrate through the transparent color unit without being color filtered and thereby a white color unit 201 can be formed. In such a manner, four subpixels on the array substrate 10, which correspond to a red color unit 210, a green color unit 210, a blue color unit 210 and white color unit 201 respectively, may form a pixel unit.

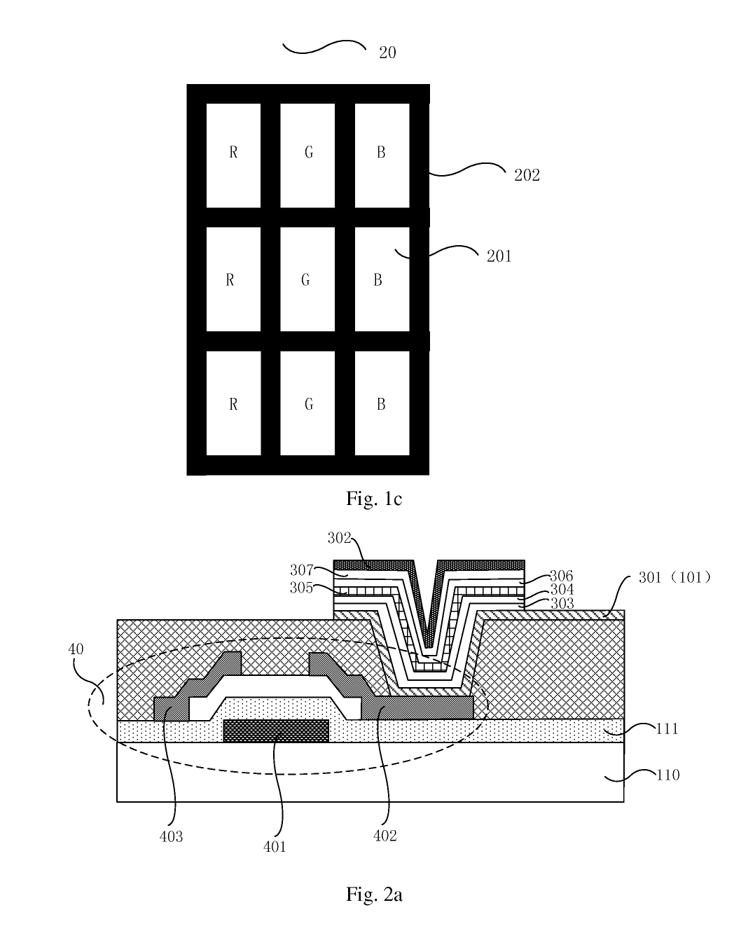

Thirdly, as shown in FIG. 2a, the OLED display structure 30 may comprise a first electrode 301, a hole injection layer 303, a hole transportation layer 304, an organic light emitting layer 305, an electron transportation layer 306, an electron injection layer 307, and a second electrode 302 sequentially located on a surface of the pixel defining layer 20. The hole injection layer 303, the hole transportation layer 304, the organic light emitting layer 305, the electron transportation layer 306 and the electron injection layer 307 are disposed in this order from the first electrode 301 to the second electrode 302 so as to constitute an organic material functional layer 310.

In one aspect, in order to simplify manufacturing process, a via-hole may be formed in the surface of the pixel defining layer 20 at a position where the OLED display structure 30 may be positioned, such that the first electrode 301 may be connected with the drain electrode 402 of the TFT 40 in a subpixel 100 through the via-hole. In such a manner, the first electrode 301 may also be used as a pixel electrode 101 on the array substrate 10.

In another aspect, for the bottom-emitting type AMOLED display panel, the first electrode 301 may formed from a transparent conductive material, such as tin indium oxide or zinc indium oxide. The second electrode 302 may be formed from a metal material. If the second electrode 302 is formed by a material having a relatively high reflectivity (for example, at least one of aluminum and silver), then when the display panel is in a non-operating state, it could be used as a mirror. A mirror surface display can thereby be provided.

In addition, when manufacturing the OLED display structure 30, a thickness of the organic material functional layer 310 may be the same as a thickness of the pixel defining layer 20, as shown in FIG. 2b. In such a way, a flat second electrode 302 may be formed on the entire surface of the pixel defining layer 20. A plurality of OLED display structures 30 share one second electrode 302. Because the second electrode 302 on the AMOLED display panel is manufactured through a single process, such as spray coating or sputtering, and the manufactured second electrode 302 has a flat surface, a ghost phenomenon in mirror reflection due to different heights at different positions of a total reflective layer during a mirror surface display may be abated.

FIG. 2b illustrates an AMOLED display panel having another configuration, where the AMOLED display panel further comprises an insulation layer 112 located between the pixel electrode 101 and the drain electrode 402 of the TFT 40. The insulation layer 112 may be formed from a transparent resin material so as to prevent an electric leakage of the TFT 40 that will cause a bad influence on the display panel.

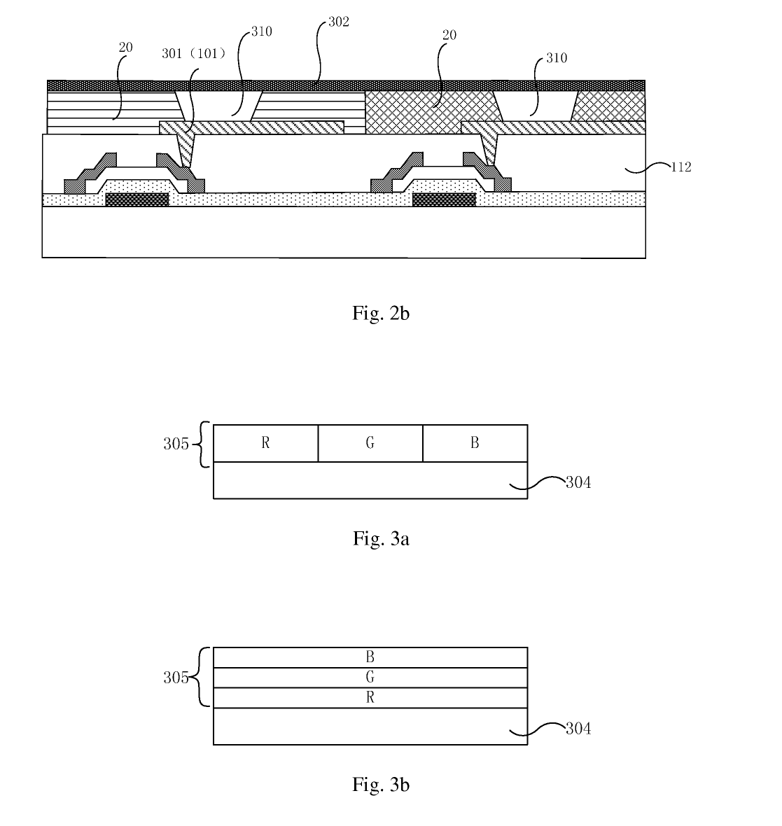

Fourthly, since the above OLED display structure 30 can emit white light, the organic light emitting layer 305 of the OLED display structure 30 may comprise a red organic light emitting layer (R), a green organic light emitting layer (G), and a blue organic light emitting layer (B) stacked in an arbitrary order on a surface of the hole transportation layer 304, as shown in FIG. 3b.

The red organic light emitting layer (R), the green organic light emitting layer (G), and the blue organic light emitting layer (B) may be formed through, for example, an evaporation coating process. In an exemplary embodiment, firstly, a red organic light emitting layer may be formed through evaporation coating on a surface of the hole transportation layer 304; then a green organic light emitting layer is formed through evaporation coating on a surface of the red organic light emitting layer; and next, a blue organic light emitting layer is formed through evaporation coating on a surface of the green organic light emitting layer. An organic light emitting layer 305 having a different stacked order may be formed through a similar method, which is omitted herein.

Alternately, the organic light emitting layer 305 of the OLED display structure 30 may comprise: a red organic light emitting layer (R), a green organic light emitting layer (G), and a blue organic light emitting layer (B) arranged side by side in an arbitrary order in the same layer, as shown in FIG. 3a.

Specifically, strip-shaped red organic light emitting layer (R), green organic light emitting layer (G), and blue organic light emitting layer (B) may be formed through three exposure processes using the same mask. In other two exposure processes after the first exposure process, the mark should be displaced to prevent the organic light emitting layers from being overlapped with each other.

Fifthly, in order to improve light filtering performance of the pixel defining layer 20 formed by a color filter layer, a thickness of the color filter layer may be limited in a range of 1-4 μm. Preferably, the thickness of the color filter layer may be limited in a range of 2-4 μm, and even more preferably, in a range of 3-4 μm. Thus, when the pixel defining layer 20 is formed by a color filter layer, a thickness of the color filter layer is increased, a distance between the data line Data on the array substrate 10 and the second electrode 302 in the OLED display structure 30 is increased, coupling capacitance formed by the data line Data and the second electrode 302 is decreased, and thus power consumption of the display panel is reduced.

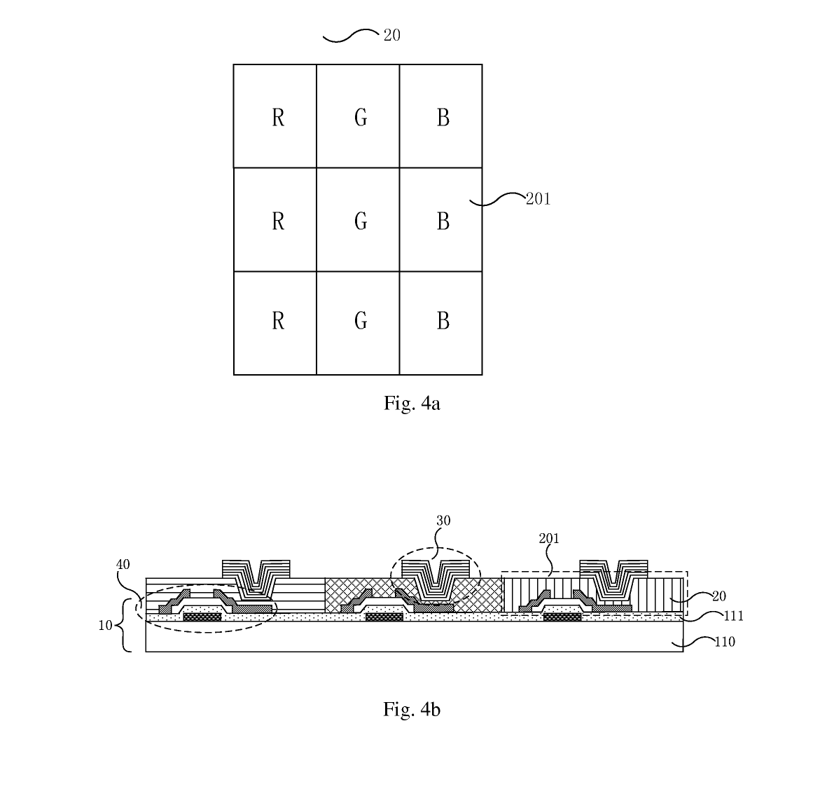

In order to further improve performance of an AMOLED display panel when it is used as a mirror surface display, an AMOLED display panel having a different structure is provided in the invention, as shown in FIG. 4b. The pixel defining layer 20 is formed only by a color filter layer and each color unit 201 of the color filter layer corresponds to one of the subpixels 100 respectively, as shown in FIG. 4a. In such a manner, when the second electrode 302 of the OLED display structure is made from aluminum or silver having a relatively high reflectivity, all the incident light on the second electrode 302 can be reflected and thereby a total reflection can be realized, because there is no black matrix 202 in the display panel to block the light. Thus, a mirror surface display effect is improved when the display panel is used as a mirror.

An embodiment of the invention provides a display device, which comprises an AMOLED display panel according to any one of the above embodiments, and has the same structure and advantageous effect as those of the AMOLED display panel according to aforementioned embodiments. A detailed description of the structure and advantageous effect of the AMOLED display panel will be omitted herein, since it has been provided as above in the aforementioned embodiments.

To be noted, the display device may comprise a display, a TV set, a digital frame, a mobile phone, a tablet computer or other products or components having a display function.

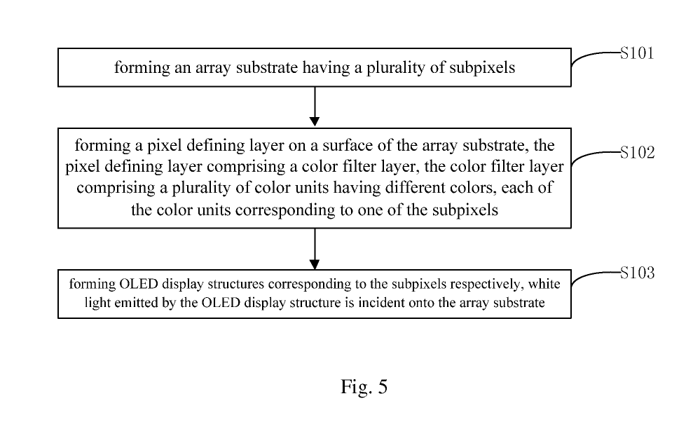

An embodiment of the invention provides a manufacturing method of the AMOLED display panel. As shown in FIG. 5, the method may comprise steps as follows:

Step S101: forming an array substrate 10 having a plurality of subpixels 100.

Specifically, a gate electrode 401, a gate insulation layer 111, an active layer, a source electrode, and a drain electrode 402 of the TFT 40, an insulation layer 112, and a pixel electrode 101 connected with the drain electrode 402 of the TFT 40 through a via-hole formed in a surface of the insulation layer 112 may be successively formed through patterning processes on a surface of an underlying substrate 100 made from glass.

To be noted, the patterning processes may comprise a lithography process, or may comprise a lithography process and an etching process, and it may also comprise printing, ink-jetting and other processes for forming a predetermined pattern. The lithography process refers to a process in which a pattern is formed through steps of film-forming, exposure, developing and the like using photoresist, mask, and exposure machine and the like. A suitable patterning process may be chosen based on the structure formed according to the invention.

Step S102: forming a pixel defining layer 20 on a surface of the array substrate 10, the pixel defining layer 20 comprises a color filter layer; wherein the color filter layer comprises a plurality of color units 201 having different colors, and the color units 201 correspond to the subpixels 100 on the array substrate 10 respectively.

Specifically, the pixel defining layer 20 may be consisted of a black matrix 202 and a plurality of spaced-apart color units. Each color unit 201 corresponds to one pixel electrode 101 of the subpixels 100 on the array substrate 10, and the black matrix 202 corresponds to regions of the subpixels 100 except the pixel electrodes 101. In such a manner, the black matrix 202 can shield a control circuit (e.g., a region where a TFT 40 is located) disposed on the array substrate 10, so as to prevent light from irradiating to the above control circuit and causing damage to the circuit.

Specifically, the black matrix 202 shown in FIG. 1a may be formed first on a surface of the substrate on which the pixel electrode 101 (or the first electrode 301 of the OLED display structure 30) has been formed, then color units 201 having different colors are formed on the black matrix 202 through patterning processes so as to form the color filter layer.

As to a RGB display device, colors of the color units 201 may comprise red (R), green (G), and blue (B). In such a manner, three subpixels on the array substrate 10, which correspond to one red color unit 201, one green color unit 201 and one blue color unit 201 respectively, may form one pixel unit.

As to a RGBW display device, a color unit 201 may be a red (R) color unit, a green (G) color unit, a blue (B) color unit, or a transparent color unit 201 which does not have any color, such that white light emitted by an OLED can penetrate through the transparent color unit without being color filtered and thereby a white color unit 201 can be formed. In such a manner, four subpixels on the array substrate 10, which correspond to one red color unit 201, one green color unit 201, one blue color unit 201 and one white color unit 201 respectively, may form a pixel unit.

Specifically, strip-shaped red color unit 201, green color unit 201, blue color unit 201, and transparent white color unit 201 for emitting white light may be formed through four exposure processes using the same mask. In other exposure processes after the first exposure process, the mark should be displaced to prevent the organic light emitting layers from being overlapped with each other.

Step S103: forming OLED display structures 30 on a surface of the defining layer 20 so as to correspond to the subpixels 100 respectively. White light emitted by the OLED display structures 30 is incident onto the array substrate 10.

Specifically, as shown in FIG. 2b, an already formed pixel electrode 101 may be used as the first electrode 301 of the OLED display structure 30; then, a hole injection layer 303, a hole transportation layer 304, an organic light emitting layer 305, an electron transportation layer 306 and an electron injection layer 307 are successively formed on a surface of the first electrode 301 through evaporation coating. Next, a metal layer is formed on an entire surface of the display structure through a coating or a sputtering process so as to form a second electrode 302 of the OLED display structure 30. As stated above, the metal material of the second electrode 302 may be aluminum or silver, such that a total reflection layer is formed to realize a mirror surface display.

Furthermore, in order that the OLED display structure 30 can emit white light, the organic light emitting layer 305 of the OLED display structure 30 may comprise a red organic light emitting layer (R), a green organic light emitting layer (G), and a blue organic light emitting layer (B) arranged in stack in an arbitrary order on a surface of the hole transportation layer 304, as shown in FIG. 3b.

The red organic light emitting layer (R), the green organic light emitting layer (G), and the blue organic light emitting layer (B) may be formed through an evaporation coating process. For example, firstly, a red organic light emitting layer may be formed through evaporation coating on a surface of the hole transportation layer 304; then a green organic light emitting layer is formed through evaporation coating on a surface of the red organic light emitting layer; and next, a blue organic light emitting layer is formed through evaporation coating on a surface of the green organic light emitting layer. An organic light emitting layer 305 having a different stacked order may be formed through a similar method, which is omitted herein.

Alternately, the organic light emitting layer 305 of the OLED display structure 30 may be configured to comprise: a red organic light emitting layer (R), a green organic light emitting layer (G), and a blue organic light emitting layer (B) arranged side by side in the same layer and arranged in an arbitrary order, as shown in FIG. 3a.

Specifically, strip-shaped red organic light emitting layer (R), green organic light emitting layer (G), and blue organic light emitting layer (B) may be formed through three exposure processes using the same mask. In other two exposure processes after the first exposure process, the mark should be displaced to prevent the organic light emitting layers from being overlapped with each other.

A manufacturing method for the AMOLED display panel provided in an embodiment of the invention comprises a step of forming an array substrate having a plurality of subpixels. Then a pixel defining layer is formed on a surface of the array substrate, wherein the pixel defining layer comprises a color filter layer; wherein the color filter layer comprises a plurality of color units having different colors, and the color units correspond to the subpixels on the array substrate respectively. In such a manner, a pixel unit may be constituted by three subpixels respectively corresponding to red, green, and blue color units, so that a full color display of the AMOLED display panel can be realized. Finally, OLED display structures corresponding to the subpixels respectively are formed on a surface of the pixel defining layer. Wherein, white light emitted from the OLED display structure irradiates to the array substrate 10 so as to provide a bottom emitting type AMOLED display panel. Since the pixel defining layer is formed by a color filter layer, there is no need to add a color filter substrate on a surface of the array substrate close to a light emitting side of the AMOLED display panel. A thickness of the AMOLED display panel can thereby be reduced.

In order to further improve performance of an AMOLED display panel when it is used as a mirror surface display, another manufacturing method for an AMOLED display panel is further provided in the invention. Specifically, in the event that the subpixels 100 comprise a pixel electrode 101, a method of forming the pixel defining layer 20 comprises a step of:

forming the pixel defining layer 20 only by a color filter layer on the surface of the array substrate 10, as shown in FIG. 4a,

wherein, color units 201 correspond to the subpixels 100 respectively. In such a manner, when a second electrode 302 of an OLED display structure is made from aluminum or silver having a relatively high reflectivity, all the incident light on the second electrode 302 can be reflected and thereby a total reflection can be realized, because there is no black matrix 202 in the display panel that blocks the light. Thus, a mirror surface display effect is improved when the display panel is used as a mirror.

All that has described above are just specific ways of implementing the invention, and the scope of the invention is not limited thereto. All changes or substitutions that are obvious to those skilled in the art based on the disclosure of the invention shall fall within the scope of the invention. Therefore, the scope of the invention is defined by the attached claims.

1. An Active Matrix Driving Organic Light Emitting Diode (AMOLED) display panel, comprising:
an array substrate having a plurality of subpixels;
a pixel defining layer located on a surface of the array substrate; and
a plurality of Organic Light Emitting Diode (OLED) display structures corresponding to the subpixels respectively, wherein
the pixel defining layer comprises a color filter layer; and
the color filter layer comprises a plurality of color units having different colors, and the color units correspond to the subpixels respectively.

2. The AMOLED display panel according to claim 1, wherein
the pixel defining layer is only consisted of the color filter layer.

3. The AMOLED display panel according to claim 1, wherein each OLED display structure comprises a first electrode, a second electrode opposite to the first electrode, and an organic material functional layer disposed between the first electrode and the second electrode; and wherein the organic material functional layer comprises a hole injection layer, a hole transportation layer, an organic light emitting layer, an electron transportation layer, and an electron injection layer disposed successively from the first electrode to the second electrode.

4. The AMOLED display panel according to claim 3, wherein the second electrode is formed of a material having a high reflectivity.

5. The AMOLED display panel according to claim 4, the material comprises at least one of aluminum and silver.

6. The AMOLED display panel according to claim 4, wherein the first electrode is connected to a drain electrode of a thin film transistor in the subpixel through a via-hole formed in the pixel defining layer.

7. The AMOLED display panel according to claim 3, wherein the organic light emitting layer comprises a red organic light emitting layer, a green organic light emitting layer, and a blue organic light emitting layer arranged in stack in an arbitrary order.

8. The AMOLED display panel according to claim 3, wherein the organic light emitting layer comprises a red organic light emitting layer, a green organic light emitting layer, and a blue organic light emitting layer disposed side by side in the same layer in an arbitrary order.

9. The AMOLED display panel according to claim 4, wherein the organic light emitting layer has a thickness which is the same as that of the pixel defining layer.

10. The AMOLED display panel according to claim 1, wherein a thickness of the color filter layer is in range of 1 μm to 4 μm.

11. The AMOLED display panel according to claim 10, wherein the thickness of the color filter layer is in a range of 3 μm to 4 μm.

12. A display device, wherein the display device comprises the AMOLED display panel according to claim 1.

13. A method for manufacturing an AMOLED display panel, comprising steps of:
forming an array substrate having a plurality of subpixels;
forming a pixel defining layer on a surface of the array substrate, the pixel defining layer comprising a color filter layer, the color filter layer comprising a plurality of color units having different colors, each of the color units corresponding to one of the subpixels; and
forming a plurality of OLED display structures that correspond to the subpixels respectively.

14. The method according to claim 13, wherein when the subpixel comprises a pixel electrode, the step of forming the pixel defining layer comprises:
forming, on the surface of the array substrate, a pixel defining layer only consisted of the color filter layer.

15. The method according to claim 13, wherein the step of forming the OLED display structure comprises:
forming a via-hole in the pixel defining layer; and
forming the OLED display structure in the via-hole.

16. The method according to claim 13, wherein the step of forming the OLED display structure comprises:
forming a first electrode;
forming an organic material functional layer on the first electrode; and
forming a second electrode on the organic material functional layer.

17. The method according to claim 16, wherein the step of forming organic material functional layer comprises:
forming a hole injection layer, a hole transportation layer, an organic light emitting layer, an electron transportation layer, and an electron injection layer successively through evaporation coating processes.

18. The method according to claim 17, wherein the step of forming the organic light emitting layer comprises:
forming, through evaporation coating processes, a red organic light emitting layer, a green organic light emitting layer and a blue organic light emitting layer stacked up in an arbitrary order.

19. The method according to claim 17, wherein the step of forming the organic light emitting layer comprises:
forming, through mask exposure processes, a red organic light emitting layer, a green organic light emitting layer, and a blue organic light emitting layer arranged side by side in an arbitrary order in the same layer.

20. The method according to claim 16, wherein the step of forming the second electrode comprises:
forming the second electrode from a material having a high reflectivity.
